(19) United States
(12) Patent Application Publication
(10) Pub. No.: US 2017/0294572 A1
(43) Pub. Date: Oct. 12, 2017

(54) SPIN TRANSPORT ELECTRONIC DEVICE

(71) Applicants: YEDA RESEARCH AND DEVELOPMENT CO. LTD., Rehovot (IL); YISSUM RESEARCH DEVELOPMENT COMPANY OF HEBREW UNIVERSITY OF JERUSALEM LTD., jERUSALEM (IL)

(72) Inventors: Ron NAAMAN, Yarkona (IL); Nirit KANTOR-URIEL, Rehovot (IL); Shinto P. MATHEW, Rehovot (IL); Yossef PALTIEL, Maskeret Batya (IL); Oren BEN-DOR, Beit Zayit (IL); Shira YOCHELIS, Ness Ziona (IL); Nir PEER, Kfar Vradim (IL)

(21) Appl. No.: 15/128,609

(22) PCT Filed: Mar. 25, 2015
(86) PCT No.: PCT/IL2015/050325

§ 371 Date: Sep. 23, 2016

(51) Int. Cl. H01L 43/04; G11C 13/04; G11C 11/18; H01L 43/06; G11C 11/16

(52) U.S. Cl. CPC H01L 43/04; H01L 43/065; G11C 11/161; G11C 11/18; G11C 13/043

(57) ABSTRACT

An electronic device is presented, the device comprises: a spin accumulating structure; a spin selective filter electrically connected at a first end thereof to a first surface of said spin accumulating layer structure; a charge carrier source attached to said spin selective filter at a second end of the spin selective filter; wherein the spin selective filter is configured to allow passage of the charge carriers having a predetermined spin orientation from the charge carrier source to the spin accumulating structure, thereby causing a variation of spin distribution of the charge carriers within the spin accumulating structure. The device comprises further at least first and second pairs of electrical contacts which are connected to the spin accumulating structure and define first and second electrical paths through said spin accumulating structure, said first and second electrical paths intersecting within said spin accumulating structure. The device including a circuit configured to apply an electrical current between the first pair of electrical contacts and to detect the variation of spin-distribution of charge carriers within the spin accumulating structure by determining electrical voltage between the second pair of electrical contacts in response to the applied electrical current.

### TECHNOLOGICAL FIELD

The present invention relates to electronic devices such as memory, switches and logic devices and is particularly related to spin based electronic devices.

### BACKGROUND

As electronic devices are minimized in dimensions, the use of nanostructures and their corresponding electronic properties takes larger and larger part in design, development and manufacturing of such devices. Further miniaturization and increase in energetic efficiency take high-priority part in corresponding research and development of new devices. Different approaches pursuing operational schemes for nano- and micro-devices are known, including the use of spin transport electronics (spintronics). Differently than charge based operations when an electron, or its absence (i.e. hole), is the main element used. Spintronics based devices utilize the inner magnetic moment of the electrons as the important, measurable degree of freedom.

Control of spin transport and spin selective electron transmission techniques and devices are generally associates with magnetic or magnetized materials having high spin-orbit coupling. These techniques suffer from low efficiency and may often require the use of static magnets, which are relatively large in dimension.

Recent spin selective transmission approaches utilize chiral and/or helical molecules. Various types of molecules having chiral or helical structural characteristics function as spin selective filtering elements. More specifically, such chiral or helical molecules operate, even at room temperature conditions (as well as increased temperatures) to filter transmission of electrons along the molecule in accordance with direction of internal magnetic moment (spin) of the electrons. This feature of chiral and helical molecules is described by Ron Naaman et al “Spintronics and Chirality: Spin Selectivity in Electron Transport Through Chiral Molecules”, Ann. Rev. Phys. Chem. 66, 263-81 (2015). DOI: 10.1146/annurev-physchem-040214-121554.

Various techniques are known utilizing the spin filtering effects of chiral molecules, for example:

US 2012/0223294 relates to a method and a device for providing a current of spin-polarised electrons. More particularly, the present invention is suited for use in spin electronics or detection of spin-polarised electrons.

US 2015/0049542 describes a spins selective device, including a first layer comprising a ferromagnetic material. The spin selective device further includes a second layer coupled to the first layer. The second layer includes at least one molecule having a specified chirality, such that when an electrical current flows between the first layer and the second layer one or more regions of the ferromagnetic material become magnetically polarized along a certain direction.

### GENERAL DESCRIPTION

There is a need in the art for a novel configuration of an electronic device utilizing spin filtering and local spin based magnetization. The technique of the invention utilizes spin selective filter for local magnetization of a spin accumulating layer (e.g. made of a ferromagnetic material, semiconductor etc.). Additionally, the technique utilizes interaction between the accumulated spins in the spin accumulating layer and electric current flowing therein to provide information about magnitude and direction of magnetic moment generated by the spins. This interaction may be detected based on the parallel giant magneto-resistance and/or Hall Effect measurements.

The present invention provides a novel electronic device configuration utilizing a spin selective filter, e.g. in the form of chiral or helical molecules, for generating local magnetization in a spin accumulating layer structure. Further, the electronic device of the invention eliminates the need for a static magnet, which is generally required in magnetic memory units and/or other magnetic based electronic devices. To this end the device of the invention utilizes a novel configuration enabling detection of local magnetization, or reading of the data stored in the memory unit, utilizing magnetization effects on electric current such as Hall Effect. It should be noted that the omission of a permanent magnet, which is generally used for readout of local magnetization/magnetic direction, enable the device of the present invention to be configured in nanometric dimensions. Additionally, manufacturing costs may be reduced as the need for complex multilayer structure enabling to maintain permanent magnetic field is omitted. The device configuration according to the invention, as well as the corresponding readout configuration including electric connection to the at least first and second pairs of electric contacts, enables efficient three-dimensional closed packaging of the device for used in three dimensional magnetic memory packaging applications.

To this end the electronic device includes at least two pairs of electric contacts, enabling selective transmission of electric current through the device and measurement of electric voltage generated by interaction of the applied electric current and the induced local magnetization of the device. Each pair of electric contacts defines a path passing through an active region of the device, where local magnetization may be generated. Also, the paths defined by the arrangement of at least two electric contacts, are intersecting within the active region. Preferably, the path defined by the second pair of electrodes is perpendicular to the path defined by the first pair of electrodes.

More specifically, the device generally comprises a spin accumulating layer structure defining the active region where data may be written by generating/inducing local magnetization. A spins selective filter layer, e.g. in the form of plurality of chiral or helical molecules, is located on top of the spin accumulating layer structure and is in electrical contact thereto. On the other side of the spin selective filter, a charge source is attached, typically in the form of a plurality of nanocrystals or nano dots. The electronic device may be operated for selectively storing data piece within the spin accumulating structure; reading/detecting the data piece within the spin accumulating structure; and erasing the stored data.

Data may be stored on the device by optical illumination of the nanocrystals (NC's) with a predetermined wavelength range. The nanocrystals may be semiconductor nanocrystals, and are generally configured to generate free charge carriers in response to the optical illumination (photoemission effect). The above arrangement of the spin selective filter in between the charge source (nanocrystals/nano dots) and the spin accumulating structure, allows transmission of the photoemission induced charge carriers, typically electrons, from the nanocrystals, through the spin selective filter to the spin accumulating structure. However, the spin selective filter allows selective transmission of electrons therethrough, such that electrons having one predetermined spin orientation are transferred from the NC's to the spin accumulating structure and electrons having the opposite spin orientation are transferred from the spin accumulating structure to the NC's. This varies spin distribution within the spin accumulating structure, thereby generating local magnetization within the spin accumulating structure. The proper selection of ferromagnetic and/or semiconductor materials for the spin accumulating structure allows long time maintenance of the local magnetization in order to store data within the device.

Reading of stored data is generally performed by detection of the local magnetization pattern in the spin accumulating structure to determine what data piece is written (in a single bit the data piece may be I or 0, the device may be configured to operate for single bit storage or multi-bit storage including several data pieces). As indicated above, the electronic device of the invention is configured to enable readout without any use or need for a static magnet. Realization of a static permanent magnet in small dimensions, typically sub-micrometer in size, is complicated and requires layered structures increasing both the size and cost of magnetic devices. Thus the electronic device of the present invention may be configured in nanometric scale.

Readout of data stored in the electronic device of the invention may be provided utilizing electric current transmitted through the spin accumulating structure between a first pair of electric contacts. The current flowing through the spin accumulating structure interacts with the local magnetization to exhibit Hall Effect (voltage generated in response to the electric current and in a perpendicular direction to the current), or in low temperatures using giant magnetoresistance effect. Generally, in the Hall-based readout configuration, current is transmitted between a first pair of electric contacts, and the so induced voltage between a second pair of contacts, defining an intersecting path (preferably perpendicular) is measured. As generally known from Hall Effect, the perpendicular voltage is indicative of the magnetic field, which in the present case, results in the magnetization of the spin accumulating structure. For example, detecting Hall voltage above a predetermined threshold indicates I data piece, and voltage below the threshold indicates 0 data piece, or vice versa.

Additionally, transmission of a relatively higher current through the spin accumulating structure may be used for erasing the written data to allow reuse of the device. Generally, the high (above a predetermined threshold) current may increase the thermal fluctuations of the electrons' spins and equilibrate the spin distribution to erase the data (i.e. remove/reduce local magnetization).

Also, the device according to the present invention may be used as a spintronics logic unit providing output data in the form of a voltage signal in response to input data in the form of an optical signal on the charge source thereof. Such device may be operated in combination with additional magnetic based electronic device utilizing giant magneto-resistance effects to link one logic function to others. More specifically, utilizing suitable ferromagnetic layer in the spin accumulating structure, current passing therethrough may be spin dependent thus enabling detection of additional magnetically oriented elements.

Thus, according to a broad aspect of the present invention, there is provided an electronic device comprising: a spin accumulating layer structure; a spin selective filter electrically connected, at a first end thereof, to a first surface of said spin accumulating layer structure; a charge carrier source attached to said spin selective filter at a second end of the spin selective filter; and at least first and second pairs of electrical contacts which are electrically connected to the spin accumulating layer structure and define first and second electrical paths passing through and intersecting in said spin accumulating layer structure; thereby providing for detecting variation of spin distribution of charge carriers within the spin accumulating layer structure by determining electrical voltage between the second pair of electrical contacts in response to an electrical current between the first pair of electrical contacts.

According to some embodiments, the charge carrier source may be in the form of a plurality of nanocrystals configured to generate free charge carriers in response to input electromagnetic radiation of a predetermined frequency range. Alternatively, or additionally, the charge source may include other types of photoactive molecules or particles such as dye molecules or any other efficient light absorbing molecules or particles.

Additionally, according to some embodiments, the spin selective filter may comprise a plurality of molecules having chiral or helical structure of one specific handedness. The plurality of nanocrystals or light-absorbing molecules may generally be attached to the corresponding chiral or helical molecules.

According to some embodiments of the invention, the spin selective filter may be configured to allow passage of the charge carriers having a predetermined spin orientation from the charge carrier source to the spin accumulating layer structure, thereby causing said variation in spin distribution of the charge carriers within the spin accumulating layer structure. The variation in spin distribution within the spin accumulating structure may be indicative of data pieces being stored in said spin accumulating layer structure. Additionally or alternatively, the variation in spin distribution within the spin accumulating structure may be indicative of input data provided to the charge carrier source.

Generally, the spin accumulating structure may comprise at least one ferromagnetic layer. The ferromagnetic layers are preferably sufficiently thin to allow generation of stable out-of-plane magnetization. In some embodiments, the thin ferromagnetic layer may be of thickness below 7 nm.

Additionally or alternatively, the spin accumulating structure may comprise at least one semiconductor layer.

It should be noted that the spin accumulating structure may be a single layer structure or it may comprise two or more layers.

According to some embodiments, the electronic device may be configured and operable as a spintronics memory unit, in which data pieces are written and stored in the spin accumulating structure in the form of said variation of spin distribution of charge carriers within the spin accumulating structure, and is readable by passing the electric current through spin accumulating structure. The stored information may be erased by passing electric current above a predetermined value through said spin accumulating structure.

According to yet some embodiments, the electronic device may be configured and operable as a spintronics logic unit, in which output data in the form of voltage between the second pair of electrodes is determined in accordance with input data in the form of input illumination on the charge source.

According to yet some embodiments of the invention, the electronic device may be configured and operable as a Hall sensor. In some other embodiments, the device may be configured and operable for generating local magnetic fields, e.g. for Magnetic-Resonance (nuclear magnetic resonance-NMR or electron paramagnetic resonance-EPR) systems.

It should be noted, and also indicated above with reference to the use of the device of the present invention as memory unit, that the device configuration and corresponding electrical contacts to the at least first and second electric contacts thereof allows for efficient and simple three-dimensional packaging of the device when used as memory unit, spin-based logic unit as well as magnetic field generator and/or sensor. Such three-dimensional packaging allows for efficient use of space and minimizing of total size of an integrated electronic system utilizing electronic devices provided by the present invention.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIGS. 1A to 1C illustrate an electronic device according to embodiments of the present invention; FIG. 1A shows a side view of the device, FIG. 1B shows a top view of the device and FIG. 1C shows a side view of one other configuration of the device;

FIGS. 2A and 2B illustrate the electronic device according to some embodiments of the present invention; FIG. 2A shows device configuration and FIG. 2B exemplify operation of the spin selective filter layer;

FIG. 3 illustrates one other configuration of the device according to some embodiments of the invention;

FIG. 4 illustrates an optical experimental setup used in determining operation of the device according to embodiments of the invention;

FIG. 5 shows magnetic response of a device according to some embodiments of the invention;

FIG. 6A and 6B show additional measurements of magnetic response of the device according to some embodiments of the invention; and

FIG. 7 shows temperature dependent response of the device according to some embodiments of the invention.

### DETAILED DESCRIPTION OF EMBODIMENTS

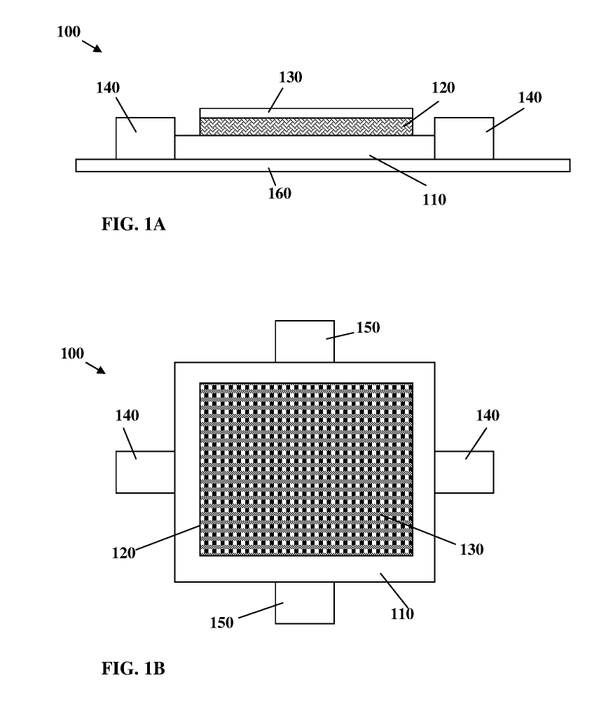

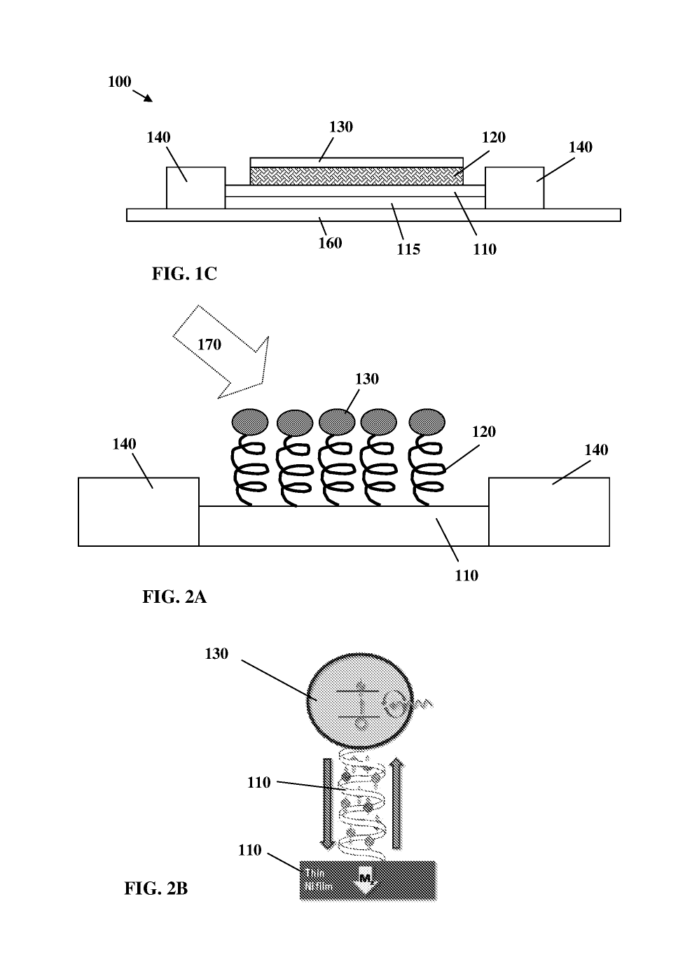

The use of chiral and helical molecules as spin filters opens a window for various novel types of electronic devices and operation thereof. Reference is made to FIGS. 1A-1C illustrating an electronic device 100 according to embodiments of the present invention. FIG. 1A illustrates a schematic side view of the electronic device 100; FIG. 1B illustrates a schematic top view of the device; and FIG. 1C illustrates a side view of the electronic device utilizing a bi- or multi-layer structure.

The device 100 includes a spin accumulating layer structure 110 placed on an electrically insulating substrate 160. A spin selective filter layer 120, e.g. formed by a plurality of chiral or helical molecules having one defined handedness, is electrically connected at a first end thereof to a first surface of the spin accumulating layer structure 110. The spin selective filter 120 is connected at another end thereof to a charge carrier source layer 130. The charge carrier 130 is configured to generate free charged particles (e.g. electrons) in response to input energy. The charge carrier source 130 may be in the form of plurality on nanocrystals (NC), e.g. semiconductor nanocrystals, attached to the spin selective filter 120. For example, each molecule of the spin selective filter 120 may be adsorbed on the surface of the spin accumulating layer structure 110 at one end thereof, and attached at its other end to a NC particle.

The spin accumulating layer structure 110 is placed in electrical connection with at least first and second pairs of electrically conductive contacts 140 and 150. Each of the at least first and second pairs of electrical contacts 140 and 150 define respectively an electrical path through said spin accumulating layer such that the first and second paths are intersecting within the spin accumulating layer.

As described above, FIG. 1A shows a side view of the electronic device 100, illustrating the layered structure of the device; FIG. 1B shows a top view in order to demonstrate the intersecting first and second paths defined by the first and second pairs of electrical contacts. Additionally FIG. 1C illustrates a spin accumulating layer having a bi- or generally multi-layer structure. In this connection the spin accumulating layer may be formed of one ore more sub-layers (two such sub-layers are shown 110 and 115) being made of semiconductor or electrically conducting materials as will be described further below.

The device 100 may be used in electronic (or spintronics) memory unit, logic gate, switch or any other spintronics based device. According to some embodiments of the invention, pumping energy, e.g. electromagnetic/optical radiation, is used to generate free charge carriers in the charge carrier source 130. The spin selective filter 120 allows charge carriers having spin in one predetermined direction to flow from the charge source 130 to the spin accumulating layer 110 while allowing charge carriers of having spin in the opposite direction to flow from the spin accumulating layer structure 110 to the charge source 130. This varies spin distribution within the spin accumulating layer effectively generating a magnetic moment within the layer.

The spin selective filter 120 may generally be in the form of plurality of chiral or helical molecules, having one specific predetermined handedness. Such molecules allow transmission of charge carriers/electrons having pone predetermined spin orientation in one direction and the opposite spin orientation in the other direction.

In some embodiments of the present invention the electronic device 100 utilizes plurality of nano crystals (NCs) attached to the spin selective filter at its far end and operate to generate free charge carrier in response to pumping energy. More specifically as illustrated in FIG. 2A, a plurality of chiral or helical molecules are adsorbed on a top surface of the spin accumulating layer structure 110 acting as spin selective filter 120, and the plurality of NC's are attached at the other end of the molecules. The NC's are configured to generate free charge carriers in response to input pumping electromagnetic/optical radiation 170. Generated free charge carriers having spin of a predetermined orientation are transmitted through the molecules to the spin accumulating layer structure 110 while charge carriers of the opposite spin orientation can be transmitted from the spin accumulating layer structure to the NC's. This provides desirable local spin based magnetization that can be generated by optical illumination of the charge carrier source 130 even at ambient temperatures.

As indicated above, optical excitation of the NC's generates free charge carriers within the charge source 130 (e.g. NC's), the spin selective filter effectively operates to transfer spin torque from the NC's to the spin accumulating layer structure 110. This is illustrated in FIG. 2B showing spin filtering and transmission through a chiral/helical molecule to the spin accumulating layer 110. The spin accumulation results in variation in spin distribution within the spin accumulating layer 110, substantially generating local magnetic field within the layer 110. The spin accumulating layer structure 110 may generally include a ferromagnetic layer and/or a suitable doped semiconductor layer to thereby maintain the variation in spin distribution for a predetermined time period. This enables the device 100 as described above to be operated as a magnetic memory unit.

To this end, the device 100 may be operated to write and store data piece by generating a proper variation in spin distribution within the spin accumulating layer structure 110 by illuminating the charge source 130 by optical illumination 170 of suitable wavelength. Readout of the stored data piece may be provided utilizing parallel giant magneto-resistance (at low temperatures) or Hall effects by transmitting electrical current through the spin accumulating layer structure 110 between the first pair of electrodes 140. At low current, this enables detection of Hall voltage, which is measured between a second pair of electrodes 150 defining an intersecting path. Generally the paths defined by the first and second pairs of electrodes are perpendicular to each other to enable detection of Hall voltage due to local magnetization of the spin accumulating structure 110. Additional pairs of electrodes may be used to enable logic operations. Additionally, the device may provide a building block for transistor type elements, e.g. a simple parallel giant magneto-resistance transistor device, as well as and three dimensional spin based logic.

Thus, the device according to the present invention provides a memory type device enabling write and read of data while not require a static permanent magnet unit. It should be noted that such permanent magnet unit generally requires a complex layered structure and is relatively large in dimension with respect to micrometer size electronic elements. In this connection it should also be noted that the device and technique of the present invention allows the use of permanent magnet enabling readout utilizing parallel giant magneto-resistance as well as anomalous Hall Effect (AHE). However, the device is operable without such permanent magnet to support operations such as writing, reading and erasing data pieces.

To this end, local probing (readout) of the magnetic field generated by local magnetization of the spin accumulating structure is preferably achieved using Hall sensors configuration. The Hall Effect configuration makes it possible to realize a device with output voltage proportional to the local magnetization within the active region of the device.

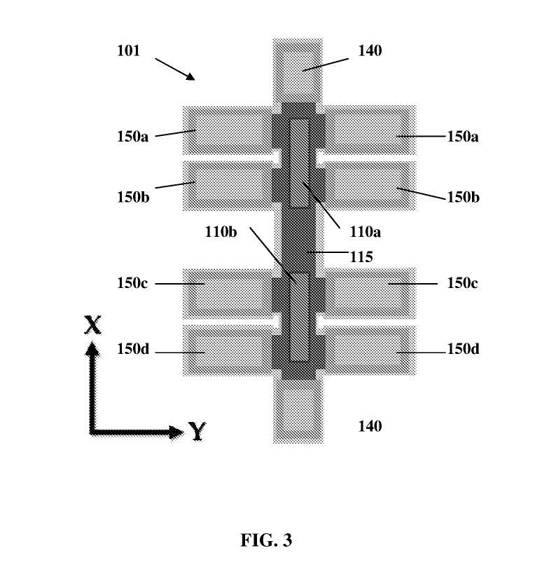

Additional configuration is illustrated in FIG. 3 showing an electronic device 101 according to some embodiments of the present invention. The device 101 is configured as a bi-layer spin accumulating structure including a first Silicon layer 115, generally doped Si (e.g. p-doped), and a second ferromagnetic thin layer (such as Nickel). In the example of FIG. 3 two active regions including Nickel layer 110a and 110b are shown, however additional active regions may be used. A layer of chiral or helical molecules is adsorbed on each of the active regions 110a and 110b, for each active region the molecules have one selected handedness; however the two or more region may include molecules of different handedness. For example, active region 110a may utilize molecules of right handedness and active region 110b may utilize molecules of left handedness. The first layer of the spin accumulating structure is electrically connected to at least a first pair of electric contacts 140 for transmission of current along the structure 110, and at least a second pair of electric contacts 150 defining a path intersecting with path defined by the first pair 140 within the structure. In the example of FIG. 3 four pairs of electric contacts are shown 150a-150d. Electric contacts 150a and 150b are associates with active region 110a and electric contacts 150c and 150d are associated with active region 110b. To this end the electronic device may be configured such the optical illumination of the NC's of an active region 110a or 110b generate variation in spin distribution within the active region, thereby causing local magnetization of the region. For thin layer of ferromagnetic material (e.g. 1-15 nm preferably 2-6 nm), the local magnetization is maintained due to spin interactions within the layer. It should be noted that thick ferromagnetic layers may result is reduced stability of the local magnetization and in generation of magnetic domains in the layer. Thus, a thin ferromagnetic layer is generally preferred, preferably below 7 nm.

The different electrode pairs 150a-150d may be used for probing of the local magnetization in the corresponding active regions 110a and 110b. As indicated above, transmission of electric current between the first electrode pair 140 results in Hall voltage in response to local magnetization in one or more of the active regions. More specifically, detection of Hall voltage between one or more of the electrode pairs 150a-150d provided data indicative of direction and magnitude of local magnetization in the corresponding active region, thereby enabling readout of stored data in the active regions 110a and 110b.

Additionally, erasing of data generally requires equilibration of the spin distribution within the active regions/spin accumulating structure 110. This is provided by passing relatively high current through the spin accumulating structure 110, i.e. between any selected pair of electrodes 140 and/or 150. Transmission of current above a corresponding threshold will redistribute the spin within the layer and effectively destroy the local magnetization to thereby erase data stored in the active region.

It should be noted that to provide data storage in the form of local magnetization, the spin accumulating structure 110 preferably configured with a thin film ferromagnetic layer. However, it should be noted that local magnetization may also be stored in semiconductor layer and/or electrically insulating layer of the spin accumulating structure.

The inventors have prepared two exemplary devices for demonstrating the principles of operation. Two types of spin accumulating structures were utilized. In the first exemplary sample, herein referred to as Si based device, the spin accumulating structure includes a bi-layered spin accumulating structure formed of a 5 nm thick Ni layer located on top of a shallow P doped Si layer (generating a shallow 2D-like hole gas) substantially similar to the example of FIG. 1C.

More specifically, an intrinsic Si wafer was Phosphor doped using ion implantation. The process utilized a dose of 10¹² ions/cm² with 5 KeV implant energy at 0° implantation angle. This implant yields a 30 nm P doped channel with a peak in ion density around 15 nm depth. Further fabrication of the Si-based spin accumulating structure included the following: etching the Si and patterning a conduction channel; evaporation followed by a liftoff process to provide gold contacts resulting in the pairs of electric contacts; passivation around the channel by deposition of 0.5 μm SiO₂ using Plasma Enhanced Chemical Vapor Deposition (PECVD) followed by wet etching to pattern the active areas; evaporating deposition of 5 nm ferromagnetic Ni layer on top of the active areas of the silicon; adsorbing of the spin selective filter in the form of chiral/helical molecules followed by the NCs adsorption; and capping the samples with evaporation of thin 10 nm Al₂O₃ protection layer. The protection layer is used to prevent Ni oxidation and to protect the active regions of the device.

The thickness of the Ni layer is generally selected to maximize perpendicular magnetization. To this end a 5 nm Nickel layer is used. As generally known, a thin Ni layer may generally break into domains allowing for a perpendicular magnetization rather than in-plane magnetization which provides limited results. Such perpendicular magnetization can be measured at room temperatures using magnetic atomic force microscopy (AFM) in the 5 nm Ni layer.

The second exemplary sample, herein referred to as Ni based device, is configured with spin accumulating structure being a single-layered structure formed of a thin Ni layer. The Nickel layer capped with protecting 10 nm gold layer Hall channel was evaporated on a thick SiO₂ insulation layer, followed by gold contacts evaporation. Before the adsorptions of the NC's, the 10 nm thin gold capping layer was etched and the samples were placed under an inert nitrogen environment. The molecules and NC's were than adsorbed without the capping layer. The 7 nm Ni thickness was enough to conduct, however the magnetization was less stable as long lived magnetic domain were achieved at lower temperatures. It should be noted that generally the Nickel layer is preferably below 7 nm in thickness to allow stable out-of-plane magnetization. It should also be noted that generally the gold layer capping may be thinner or thicker than 10 nm.

In both exemplary samples, the spin selective filter was formed by a layer of organic α helix L-Polyalanine (AHPA-L available by Sigma-Aldrich) and InAs or CdSe NC's. The helical molecules and NC's were adsorbed using several steps. First, the devices were left in absolute ethanol for 20 min before immersed into a 1 mM ethanol solution of the organic molecule for 3 hours. This procedure allows the self-assembled molecules monolayer (SAM) to form a homogeneous, closely packed single layer of molecules. The excess of the organic molecules are removed from the surface by washing the sample with ethanol for several times before the samples are dried under nitrogen. Lastly NCs are attached to the organic layer. For the purpose of the Si based device configuration, InAs NCs were used with average size of 5 nm in diameter and emission peak at 1240 nm. For the Ni based device, core CdSe NCs with emission peak at 610 nm were used.

To ensure that free charged particles are generated in the NC's and not the Silicon layer or SiO₂ insulating substrate, the energy gap of NC's is selected to be smaller than the smallest gap of the Si channel structure (1 eV for InAs vs. 1.1 eV gap of bulk Si at room temperature). This is selected to enable excitation of the NC's with minimal influence on the Si channel in the Si based device.

It should be noted that, and as indicated above, stable magnetization of the spin accumulating structure may generally depend of characteristics of the structure in combination with thermal conditions. In this connection the inventors have found that the Si based device, utilizing Al₂O₃ passivation layer and 5 nm Ni layer, showed stable magnetization at room temperatures. This while the 7 nm thick Nickel layer in the Ni based device showed stable magnetization at lower temperatures, while at room temperature, magnetic domains formed within the Ni layer. Generally reduced thickness of the Ni layer may provide stable out of plane magnetization at higher temperatures. Additionally, thin ferromagnetic layers are generally suitable to provide stable magnetization in this configuration.

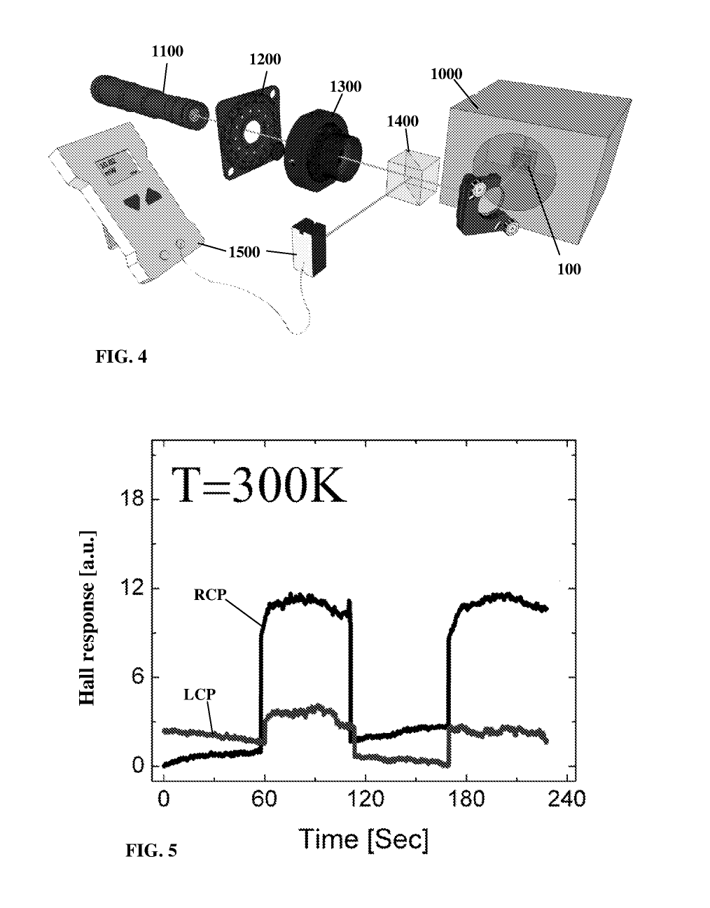

As indicated above, data pieces may be stored within a spin accumulating structure of the device 100 utilizing optical illumination of the charge source (NC's). This is exemplified in FIG. 4 showing an optical setup including a light source 1100, a linear polarizer 1200 mounted on a rotatable holder, a quarter wave plate 1300 (QWP), beam splitter 1400 and intensity detector 1500. The electronic device 100 is placed in a cooling chamber 1000 to allow measurements in temperatures between 1.5K and 300K. In this connection, optical pumping of the NC's used continuous wave (CW) laser in wavelength of 1064 nm for the InAS NC's and wavelength of 532 nm for the CdSe NC's.

The use of linear polarizer 1200 and QWP 1300 is to enable comparison between the effects of right/left circular polarization illumination (RCP/LCP) for both Hall configurations. This is provided using a linear polarizer in the optical path at angular orientations of 45° or 315° with respect to axis of the QWP. The coming laser intensity was monitored by splitting 1400 the signal between an intensity detector 1500 and the device 100 of the invention. A simple mechanical shutter is placed along the optical path to provide comparison between light and dark measurements.

To this end, the NC's of the device 100 are illuminated in cycles of 60 seconds light, followed by 60 seconds of darkness to demonstrate temporary magnetization of the spin accumulating structure. The absolute response is calculated by subtracting the offset from the Hall resistance response normalized by the total resistance.

Reference is made to FIG. 5 presenting the measured and normalized Hall response for two circular polarization illuminations. The measurements were done at similar ambient conditions and room temperature on the Si-based device as described above. In both right circular polarization (RCP) and left circular polarization (LCP) the signal under illumination is compared to the dark signal by alternating the illumination every 60 seconds between dark and light conditions. The Hall response was measured by transmitting electric current between the first pair of electrodes (140 above) while measuring the voltage between the second pair of electrodes (150 above). Based on the know charge carrier density in the p-doped silicon layer, the Hall resistance was determined. As shown in FIG. 5 it is clear that localized magnetization is achieved in both illumination conditions. However, as also shown, the response to right handed circular polarization is around A=12 (arbitrary units) while the absolute response to left handed circular polarization is around A=3. It should also be noted that the detected change in Hall resistance is three orders of magnitude smaller than the sample lateral resistance, i.e. the resistance between the first pair of electrodes (140) generally defined as ρₓₓ. It should be noted that similar illumination on a sample without NC's shows negligible magnetization, such magnetization may result due to circular polarized illumination and does not show in linear polarized or non-polarized illumination.

The large difference (asymmetry ratio of 1:4) measured between right and left circular polarizations indicated that the chiral/helical molecules layer provides spin selective filter and that local magnetization is generated even when exciting the system with non-polarized light. The measured Hall coefficient can be evaluated based on the density of holes in the p-doped Si layer (effectively operating as channel). This provides estimated local magnetization of about 120G.

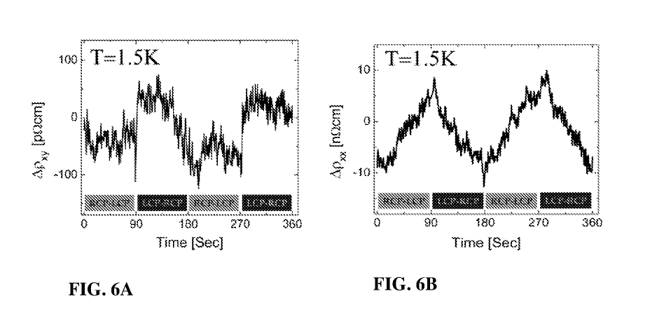

As indicated, above, the Nickel based device may generally be more flexible and simpler structure, and allows the use of a more adaptable choice of NC's. An additional advantage of the Ni-based device is that this configuration opens the way to connecting logic structures in series. FIGS. 6A and 6B illustrate perpendicular and longitudinal resistance (Δρ_{xy} and Δρₓₓ) of the Ni based spin accumulating structure (channel) under illumination of left and right circularly polarized light (LCP and RCP). The measurements were done at 1.5K. It should be noted that the results are defined as difference (Δ) indicating the difference between response to Right circular polarization minus the response to left circular polarization, thus comparing between the magnetization in a certain direction corresponding to the chiral molecules asymmetry (a-1—right circular polarization) and magnetization in the opposite direction due to left circular polarization (1-a).

As shown in FIG. 6A, the Hall resistance ρ_{xy} has very small difference in magnitude comparing between the two polarizations. It should be noted that at such low temperatures (1.5K), this small signal may result due to small anomalous Hall Effect (AHE) in ferromagnetism. In these temperatures for ferromagnetic films the spin scattering is small and therefore the effective Hall coefficient is small.

Additionally, FIG. 6B shows difference in parallel resistance Δρₓₓ measured under different light polarization excitation of the system. The increase in the resistance under RCP compared to the LCP value may be generally a result of to the giant magneto-resistance effect. The magnetization of the Ni spin accumulating structure (channel) induced scattering and therefore resistance increase or decrease according to the absolute magnetization of the structure.

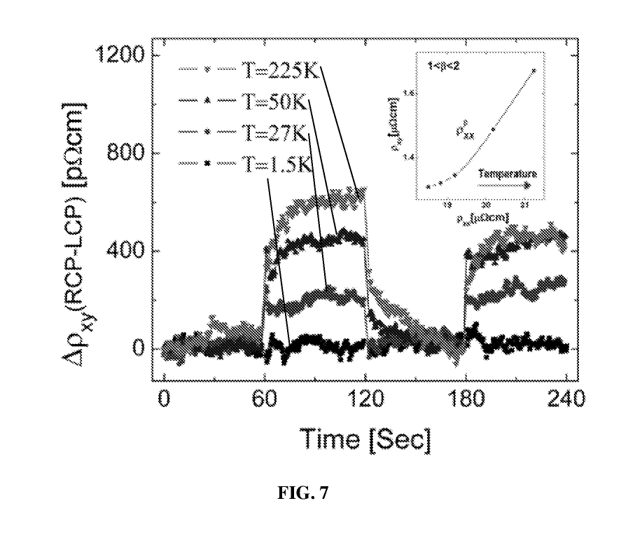

Generations of local magnetization in different temperatures in the Ni based exemplary device are shown in FIG. 7. FIG. 7 shows relative Hall resistance (ρ_{xy}) component at temperatures of 1.5K, 27K, 50K and 225K in response to optical illumination. The measured resistance is determined as the Hall resistance under Right circular polarized illumination minus the measured resistance under left circular polarized illumination. As shown, the Hall voltage response is increasing with the temperature. This result is expected from the AHE predicted behavior.

At higher temperatures, i.e. 27K and above, Δρ_{xy} LCP-RCP is increasing until the Ni demagnetization effect becomes strong. This is shown by the large increase in the asymmetry factor between measurements at 1.5K to 50K as compared to the smaller increase between the measurements at 50K to 225K. Also shown in FIG. 7 is a connection between ρ_{xy}∝ρₓₓ^{β} measured for different temperatures. The logarithmic scale fit provides 1<β<2.

Thus, the device of the present invention utilizes chiral induced spin-selectivity effect (CISS) to provide transistor or memory type electronic device. More specifically, it should be noted that the induced local magnetization may be stored within the spin accumulating structure for predetermined time period. Additionally, the operation of the device can be considered as generating voltage between a second pair of electrodes (150) in response to electric current between a first pair of electrodes (140) under the condition that local magnetization of the active region (spin accumulating layer 110) is provided.

Also, it should be noted that as the NCs relevant spin coherence time T1 at ambient temperatures is typically longer than 100 ps, which is more than an order of magnitude larger than transport times through the chiral molecules. The radiative life time is in the order of ns. Therefore, a reasonable assumption would be that the excited state of the spin does not change dramatically before charge transfer occurs. In this case changes in the Hall voltage between diffracted polarization excitations predominantly originate from the overlap between the excited state and the spin filtering direction. Thus, local magnetization may be provided utilizing the spin selective filtering of the chiral/helical molecules and may be generated utilizing illumination in linear or no polarization.

Additionally, as indicated above, as charged particles having one spin orientation are passing from the NC's to the spin accumulating layer, corresponding particles having the opposite spin orientation are transferred from the spin accumulating layer to the NC's to preserve charge. This enhances the spin accumulation and the local magnetization of the spin accumulating structure. In other words, even without charging the surface of the spin accumulating structure, the oscillating charges are passing a spin torque to the spin accumulating structure as exemplified in FIG. 2B. The spin accumulating structure generally included semiconductor or ferromagnetic layer having demagnetization time longer (typically by a few, to ten orders of magnitude) than the NCs demagnetization time. The spin accumulating structure is magnetized while the NCs return to the neutral state within the demagnetization time.

The present invention provides an electronic device configured to generate local magnetization in response to input illumination, and enables detection of the local magnetization in the form of perpendicular voltage in response to current passing through the device. The device of the invention may be used in a transistor for generating logic gates, as well as in combination with electrically conducting ferromagnetic layer allowing to utilizing a combination with an additional magnetic device. Also, the spin accumulating layer of the device may be configured to maintain magnetization for a predetermined time period to thereby operate the device as a memory unit omitting the need for static permanent magnet for read and write operations. Such device may also be used for producing strong local magnetization pulses for nuclear magnetic resonance (NMR) or Electron paramagnetic resonance (EPR) systems. In such configurations, the spin accumulating structure may include a parallel magnetized ferromagnetic layer configured to generate local perpendicular magnetization in response to spin injection through the spin selective filter layer.

1. An electronic device comprising:
(a) a spin accumulating structure;
(b) a spin selective filter electrically connected, at a first end thereof, to a first surface of said spin accumulating layer structure;
(c) a charge carrier source attached to said spin selective filter at a second end of the spin selective filter;
(d) at least first and second pairs of electrical contacts which are connected to the spin accumulating layer structure and define first and second electrical paths through said spin accumulating layer, said first and second electrical paths intersecting within said spin accumulating layer structure;
thereby providing for detecting variation of spin distribution of charge carriers within the spin accumulating layer structure by determining electrical voltage between the second pair of electrical contacts in response to an electrical current between the first pair of electrical contacts.

2. The electronic device of claim 1, wherein the charge carrier source is in the form of a plurality of nanocrystals configured to generate free charge carriers in response to input electromagnetic radiation of a predetermined frequency.

3. The electronic device of claim 2, wherein said spin selective filter comprises a plurality of molecules having chiral or helical structure of one specific handedness.

4. The electronic device of claim 3, wherein said plurality of nanocrystals comprising nanocrystals attached to said chiral or helical molecules.

5. The electronic device of claim 1, wherein said spin selective filter is configured to allow passage of the charge carriers having a predetermined spin orientation from the charge carrier source to the spin accumulating structure, thereby causing said variation in spin distribution of the charge carriers within the spin accumulating structure.

6. The electronic device of claim 5, wherein said variation in spin distribution within the spin accumulating layer structure is indicative of data pieces being stored in said spin accumulating layer structure.

7. The electronic device of claim 5, wherein said variation in spin distribution within the spin accumulating layer structure is indicative of input data provided to said spin accumulating layer structure.

8. The electronic device of claim 1, wherein said spin accumulating layer structure comprises at least one ferromagnetic layer.

9. The electronic device of claim 8, wherein said at least one ferromagnetic layer is a thin layer to thereby allow generation of out-of-plane magnetization.

10. The electronic device of claim 8, wherein said at least one ferromagnetic layer has thickness below 7 nm.

11. The electronic device of claim 1, wherein said spin accumulating layer structure comprises at least one semiconductor layer.

12. The electronic device of claim 1, wherein said spin accumulating structure comprises two or more layers.

13. The electronic device of claim 1, configured and operable as a spintronics memory unit, in which data pieces are written and stored in the spin accumulating layer structure in the form of said variation of spin distribution of charge carriers within the spin accumulating layer structure, and is readable by passing the electric current through spin accumulating layer structure.

14. The electronic device of claim 13, wherein the stored information is erased by passing electric current above a predetermined value through said spin accumulating layer structure.

15. The electronic device of claim 1, configured and operable as a spintronics logic unit, in which output data in the form of voltage between the second pair of electrodes is determined in accordance with input data in the form of input illumination.

16. The electronic device according to claim 1, being configured and operable as a Hall sensor.

17. The electronic device according to claim 1, being configured and operable for generating local magnetic fields.

18. An electronic memory device comprising:
(a) a spin accumulating structure comprising a ferromagnetic layer;
(b) a plurality of molecules having chiral or helical structure adsorbed to a surface of the spin accumulating structure in selected active regions of said spin accumulating structure causing local magnetization of said ferromagnetic layer in said selected regions, said selected regions forming data bits written in said memory device;
(c) one or more electrical contacts connected to said ferromagnetic layer, for operating the data bits in the memory device.

19. The electronic memory device of claim 18, configured and operable as a spintronics memory unit, in which data pieces are written and stored in the spin accumulating structure in the form of variation of spin distribution of charge carriers within the spin accumulating structure, and is readable by passing an electric current through said spin accumulating structure.

20. The electronic memory device of claim 18, wherein stored information is erased by passing electric current above a predetermined value through said spin accumulating structure.

21. The electronic memory device according to claim 18, being configured and operable for generating local magnetic fields.
